(19) United States
(12) Patent Application Publication
(10) Pub. No.: US 2026/0190575 A1
(43) Pub. Date: Jul. 2, 2026

(54) DISPLAY APPARATUS

(71) Applicant: AUO Corporation, Hsinchu City (TW)

(72) Inventors: Kuan-Lin Chiu, Hsinchu City (TW); Han-Chung Lai, Hsinchu City (TW); Ming-Chi Hsu, Hsinchu City (TW); Cheng-Han Chung, Hsinchu City (TW)

(73) Assignee: AUO Corporation, Hsinchu City (TW)

(21) Appl. No.: 19/307,053

(22) Filed: Aug. 22, 2025

(30) Foreign Application Priority Data
Dec. 27, 2024 (TW) 113151200
Jun. 20, 2025 (TW) 114123331

(51) Int. Cl. H10H 29/49

(52) U.S. Cl. CPC H10H 29/49

(57) ABSTRACT

A display apparatus includes a substrate and a plurality of pixel structures. The pixel structures are disposed on the substrate. Each of the pixel structures includes a plurality of pad groups, a plurality of light-emitting elements and a driving circuit structure. Each of the pixel structures is disposed in a pixel area. An effective area of the pixel area is the difference between a total area of the pixel area and an area of the pad groups in the pixel area. In the pixel area, the driving circuit structure has a low absorption region located outside the pad groups. An absorption rate of the low absorption region to a laser is less than an absorption rate of the pad groups to the laser. The area of the low absorption region is greater than 60% of the effective area and less than 90% of the effective area.

### CROSS-REFERENCE TO RELATED APPLICATION

This application claims the priority benefit of Taiwan application serial no. 113151200 and Taiwan application serial no. 114123331, respectively filed on Dec. 27, 2024 and Jun. 20, 2025. The entirety of each of the above-mentioned patent applications is hereby incorporated by reference herein and made a part of this specification.

### BACKGROUND

### Technical Field

The present disclosure relates to a display apparatus.

### Related Art

Light emitting diode display panels include an active element substrate and a plurality of light emitting diode elements transferred onto the active element substrate. Inheriting the characteristics of light emitting diodes, light emitting diode display panels have advantages such as power saving, high efficiency, high brightness, and fast response time. In addition, compared to organic light emitting diode display panels, light emitting diode display panels also have advantages such as easy color calibration, long luminous life, and no image burn-in. Therefore, light emitting diode display panels are regarded as the next generation display technology. However, when using laser bonding process to bond light emitting diodes with the active element substrate, because the region near the bonding pad often has excessively high absorption rate for laser, it results in excessively high regional temperature, causing problems such as displacement of light emitting diodes on the bonding pad and generation of bubbles on the active element substrate, which affects the manufacturing yield of light emitting diode display panels.

### SUMMARY

The present disclosure provides a display apparatus that may improve the manufacturing yield of the display apparatus.

The display apparatus of the present disclosure includes a substrate and a plurality of pixel structures. The plurality of pixel structures are disposed on the substrate. Each of the pixel structures includes a plurality of bonding pad groups, a plurality of light emitting elements, and a driving circuit structure. The plurality of bonding pad groups have a pad group geometric center, wherein each of the bonding pad groups includes at least one bonding pad. The plurality of light emitting elements are respectively bonded to the plurality of bonding pad groups. The driving circuit structure is sandwiched between the substrate and the bonding pad groups, wherein at least a portion of the driving circuit structure is electrically connected to the bonding pad groups. The pixel structures are arranged in a first direction with a first spacing. The first spacing is P₁. The pixel structures are arranged in a second direction with a second spacing. The second spacing is P₂, wherein the first direction and the second direction are alternated. Each of the pixel structures is disposed within a pixel region. A first pseudo straight line is parallel to the second direction, and the first pseudo straight line and the pad group geometric center of the pixel structure are separated by

$$\frac{{P}_{1}}{2}$$

in the first direction. A second pseudo straight line is parallel to the second direction, and the second pseudo straight line and the pad group geometric center of the pixel structure are separated by

$$\frac{{P}_{1}}{2}$$

in a third direction opposite to the first direction. A third pseudo straight line is parallel to the first direction, and the third pseudo straight line and the pad group geometric center of the pixel structure are separated by

$$\frac{{P}_{2}}{2}$$

in the second direction. A fourth pseudo straight line is parallel to the first direction, and the fourth pseudo straight line and the pad group geometric center of the pixel structure are separated by

$$\frac{{P}_{2}}{2}$$

in a fourth direction opposite to the second direction. The pixel region is enclosed by the first pseudo straight line, the second pseudo straight line, the third pseudo straight line, and the fourth pseudo straight line. An effective area of the pixel region is a difference between a total area of the pixel region and areas of the plurality of bonding pad groups within the pixel region. There is a low absorption region within the pixel region, an absorption rate of the low absorption region to a laser is less than an absorption rate of the bonding pad groups for the laser, and an area of the low absorption region is greater than 60% of the effective area and less than 90% of the effective area.

### BRIEF DESCRIPTION OF THE DRAWINGS

FIG. 1 is a top view schematic diagram of a display apparatus according to an embodiment of the present disclosure.

FIG. 2 is a cross-sectional schematic diagram of a display apparatus according to an embodiment of the present disclosure.

FIG. 3 is a top view schematic diagram of a display apparatus according to another embodiment of the present disclosure.

FIG. 4 is a cross-sectional schematic diagram of a display apparatus according to another embodiment of the present disclosure.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or ±5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the disclosure and will not be interpreted in an idealized or overly formal sense unless expressly so defined herein.

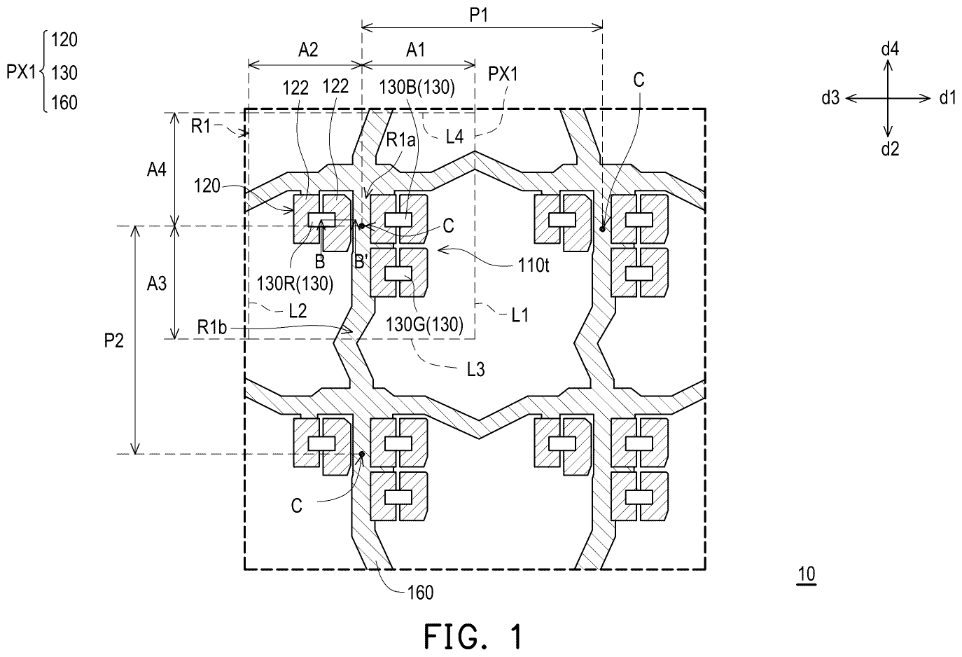

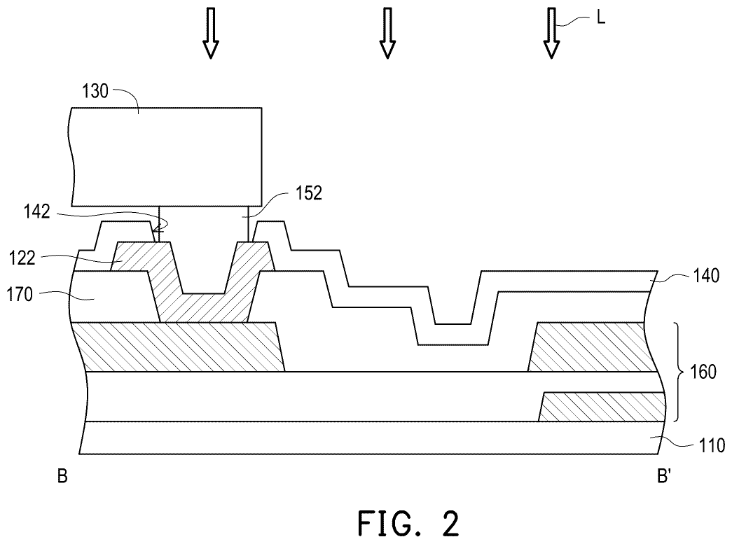

FIG. 1 is a top view schematic diagram of a display apparatus according to an embodiment of the present disclosure. FIG. 2 is a cross-sectional schematic diagram of a display apparatus according to an embodiment of the present disclosure. FIG. 2 corresponds to cross-section line B-B′ of FIG. 1.

Referring to FIG. 1 and FIG. 2, the display apparatus 10 includes a substrate 110 and a plurality of pixel structures PX1 disposed on the substrate 110. Each of the pixel structure PX1 includes a plurality of bonding pad groups 120, and the plurality of bonding pad groups 120 have a pad group geometric center C. The plurality of pixel structures PX1 are arranged in a first direction d1 with a first spacing P₁, and the plurality of pixel structures PX1 are arranged in a second direction d2 with a second spacing P₂, wherein the first direction d1 and the second direction d2 are interlaced. In other words, a distance between two pad group geometric centers C of two adjacent pixel structures PX1 arranged in the first direction d1 is P₁, and a distance between two pad group geometric centers C of two adjacent pixel structures PX1 arranged in the second direction d2 is P₂. In some embodiments, the first direction d1 may be perpendicular to the second direction d2, but the present disclosure is not limited thereto.

Each of the pixel structure PX1 is disposed within a pixel region R1. The first pseudo straight line L1 is parallel to the second direction d2, and the first pseudo straight line L1 is separated from the pad group geometric center C of the pixel structure PX1 by a distance A1 in the first direction d1, where the distance A1 is

$$\frac{{P}_{1}}{2} .$$

The second pseudo straight line L2 is parallel to the second direction d2, and the second pseudo straight line L2 is separated from the pad group geometric center C of the pixel structure PX1 by a distance A2 in the third direction d3 opposite to the first direction d1, where the distance A2 is

$$\frac{{P}_{1}}{2} .$$

The third pseudo straight line L3 is parallel to the first direction d1, and the third pseudo straight line L3 is separated from the pad group geometric center C of the pixel structure PX1 by a distance A3 in the second direction d2, where the distance A3 is

$$\frac{{P}_{2}}{2} .$$

The fourth pseudo straight line L4 is parallel to the first direction d1, and the fourth pseudo straight line L4 is separated from the pad group geometric center C of the pixel structure PX1 by a distance A4 in the fourth direction d4 opposite to the second direction d2, where the distance A4 is

$$\frac{{P}_{2}}{2} .$$

The pixel region R1 is enclosed by the first pseudo straight line L1, where the distance A4 is the second pseudo straight line L2, the third pseudo straight line L3, and the fourth pseudo straight line L4.

Each of the bonding pad groups 120 of each pixel structure PX1 includes at least one bonding pad 122. In some embodiments, each of the bonding pad group 120 may include a plurality of bonding pads 122 that are structurally separated, wherein one bonding pad 122 is electrically connected to a sub-pixel driving circuit (not shown) of the driving circuit structure 160, and another bonding pad 122 may be electrically connected to a common electrode of the driving circuit structure 160 of the display apparatus 10, but the present disclosure is not limited thereto. In some embodiments, the material of the bonding pad 122 may be metal, alloy, or a combination thereof, but the present disclosure is not limited thereto.

Each of the pixel structure PX1 further includes a plurality of light emitting elements 130, respectively bonded to the plurality of bonding pad groups 120. In some embodiments, each of the light emitting element 130 has a plurality of electrodes (not shown). The plurality of electrodes (not shown) of each light emitting element 130 are respectively electrically connected to the plurality of bonding pads 122 of a corresponding bonding pad group 120. In detail, in some embodiments, the pixel structure PX1 further includes an insulating layer 140 disposed on the bonding pads 122, the insulating layer 140 has a plurality of openings 142 respectively overlapping the plurality of bonding pads 122, and the plurality of electrodes (not shown) of the light emitting element 130 may be respectively electrically connected to the plurality of bonding pads 122 through a plurality of solders 152 (such as but not limited to: tin) located in the plurality of openings 142. In some embodiments, a laser bonding process may be used to bond the light emitting elements 130 to the bonding pad groups 120. In some embodiments, the material of the insulating layer 140 may be an inorganic material (such as: silicon oxide, silicon nitride, silicon oxynitride, or a stacked layer of at least two of the above materials), an organic material, or a combination thereof.

For example, in some embodiments, the plurality of light emitting elements 130 of the pixel structure PX1 may include a first light emitting element 130R, a second light emitting element 130G, and a third light emitting element 130B, wherein the first light emitting element 130R, the second light emitting element 130G, and the third light emitting element 130B are respectively configured to emit first colored light, second colored light, and third colored light which are different from each other. In some embodiments, the first colored light, the second colored light, and the third colored light are, for example, red light, green light, and blue light respectively, but the present disclosure is not limited thereto. In one embodiment, the light emitting element 130 is, for example, a micro light emitting diode (μLED), but the present disclosure is not limited thereto.

Each of the pixel structure PX1 further includes a driving circuit structure 160. The driving circuit structure 160 is sandwiched between the substrate 110 and the plurality of bonding pad groups 120. At least a portion of the driving circuit structure 160 is electrically connected to the plurality of bonding pad groups 120, and electrically connected to the plurality of light emitting elements 130. In some embodiments, the driving circuit structure 160 of each pixel structure PX1 may be connected to the driving circuit structure 160 of adjacent pixel structures PX1. The driving circuit structure 160 includes a plurality of metal layers 162, 164, 166, the metal layer 164 is located below the metal layer 162, and the metal layer 166 is located below the bonding pads 122 and connected to the bonding pads 122. The pixel structure PX1 further includes an insulating layer 170. The insulating layer 170 covers portions of the metal layers 162, 164, 166 of the driving circuit structure 160, and the bonding pads 122 are disposed on the insulating layer 170. The bonding pads 122 and the metal layer 162 are surface metal layers. When the display apparatus 10 is illuminated with laser L, the surface metal layers (the bonding pads 122 and the metal layer 162) directly absorb the laser L. In some embodiments, the surface metal layers include high absorption metal and low absorption metal, with light transmissive insulating layer 170 thereon without metal material. The metal layer 164 and the metal layer 166 are non-surface metal layers. In some embodiments, the material of the insulating layer 170 may be an inorganic material (such as: silicon oxide, silicon nitride, silicon oxynitride, or a stacked layer of at least two of the above materials), an organic material, or a combination thereof.

The effective area of the pixel region R1 is the difference between the total area of the pixel region R1 and the area of the plurality of bonding pad groups 120 within the pixel region R1. Within the pixel region R1, the driving circuit structure 160 has a low absorption region R1a located outside the plurality of bonding pad groups 120. In some embodiments, the low absorption region R1a includes the light transmissive region 110t. Under the laser L having the same wavelength, the absorption rate of the light transmissive region 110t to the laser L is less than the absorption rate of the plurality of bonding pad groups 120 to the laser L. The area of the low absorption region R1a located within the pixel region R1 is greater than 60% of the effective area and less than 90% of the effective area. The light transmissive region 110t is a region on the substrate 110 where the plurality of bonding pad groups 120, the plurality of light emitting elements 130, and the driving circuit structure 160 are not disposed, and light can pass through the light transmissive region 110t. In some embodiments, the material of the bonding pads 122 includes titanium. In some embodiments, the area of the light transmissive region 110t of the display apparatus 10 is relatively large, and the display apparatus 10 may be a transparent display, but the present disclosure is not limited thereto.

In some embodiments, within the pixel region R1, the driving circuit structure 160 may selectively have a high absorption region R1b located outside the plurality of bonding pad groups 120 and the light transmissive region 110t. A portion of the metal layer of the driving circuit structure 160 is a high absorption metal layer, and the high absorption metal layer is located within the high absorption region R1b. Under the laser L having the same wavelength, the absorption rate of the high absorption region R1b to the laser L is greater than or equal to the absorption rate of the plurality of bonding pad groups 120 to the laser L, that is, the absorption rate of the high absorption metal layer of the driving circuit structure 160 to the laser L is greater than or equal to the absorption rate of the bonding pads 122 to the laser L. The area of the high absorption region R1b within the pixel region R1 is greater than 10% of the effective area of the pixel region R1 and less than 40% of the effective area. That is, in some embodiments, the driving circuit structure 160 may selectively have the high absorption region R1b, but the area of the high absorption region R1b is much smaller than the area of the light transmissive region 110t.

The Laser L refers to the laser beam used in the laser bonding process. In the laser bonding process, the laser L illuminates the pixel region R1, causing the solder 152 to absorb laser L and heat up to melt, so as to connect with the bonding pads 122. Since the low absorption region R1a has a low absorption rate to the laser L, if the area ratio of the light transmissive region 110t within the pixel region R1 is too high (for example, higher than 90% of the effective area), the solder 152 may not be effectively heated and thus difficult to melt. If the area ratio of the low absorption region R1a within the pixel region R1 is too low (for example, lower than 60% of the effective area), the structures within the pixel region R1 may easily be damaged due to absorbing excessive laser L energy and generate bubbles.

In some embodiments, by maintaining the ratio of the low absorption region R1a within the pixel region R1 in a specific range (i.e., greater than 60% of the effective area and less than 90% of the effective area), during the laser bonding process, the solder 152 may be smoothly melted while the low absorption region R1a maintains a relatively low temperature so that the structures within the pixel region R1 are not damaged or generate bubbles. For example, in a 17.3-inch display apparatus 10, the area of the light transmissive region 110t of the low absorption region R1a may be greater than or equal to 70% of the effective area. In detail, by maintaining the area of the low absorption region R1a within a specific range, the display apparatus 10 may effectively reduce problems such as displacement and bubble formation of the light emitting elements 130 during the bonding process with the bonding pads 122, thereby improving the manufacturing yield of the display apparatus 10.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

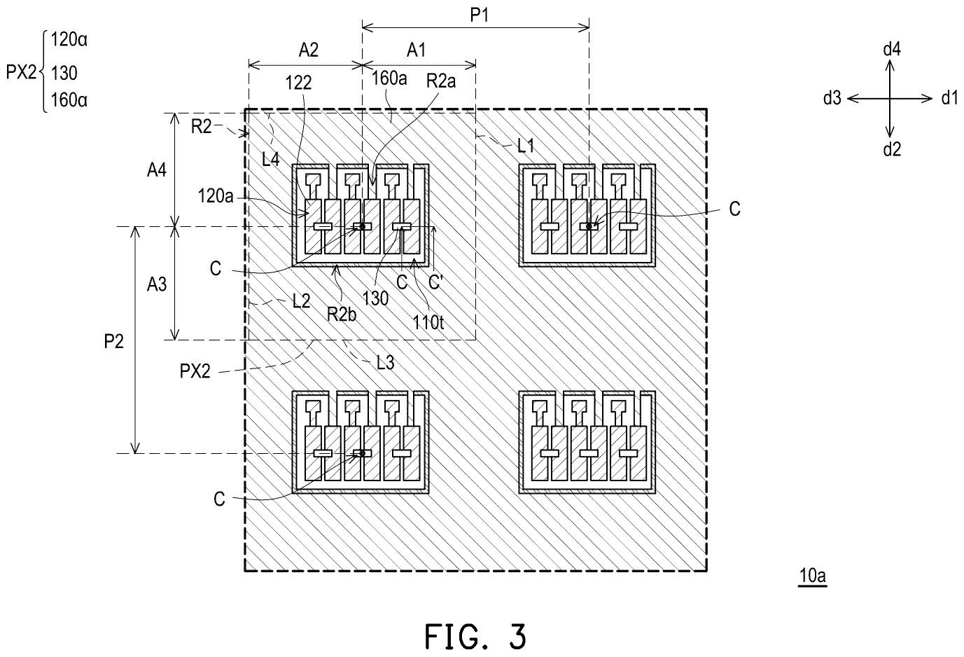

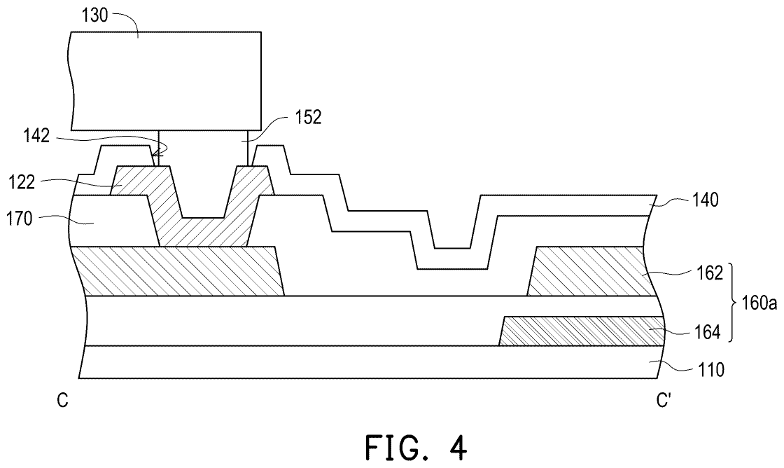

FIG. 3 is a top view schematic diagram of a display apparatus according to another embodiment of the present disclosure. FIG. 4 is a cross-sectional schematic diagram of a display apparatus according to another embodiment of the present disclosure. FIG. 4 corresponds to cross-section line C-C′ of FIG. 3. Referring to FIG. 3 and FIG. 4, the display apparatus 10a, the pixel region R2, and the pixel structure PX2 are similar to the aforementioned display apparatus 10, pixel region R1, and pixel structure PX1. The display apparatus 10a includes a substrate 110 and a plurality of pixel structures PX2. The plurality of pixel structures PX2 are disposed on the substrate 110. Each of the pixel structure PX2 includes a plurality of bonding pad groups 120a, a plurality of light emitting elements 130, and driving circuit structure 160a. The plurality of bonding pad groups 120a have a bonding pad group geometric center C, wherein each of the bonding pad groups 120a includes at least one bonding pad 122. The plurality of light emitting elements 130 are respectively bonded to the plurality of bonding pad groups 120a. The driving circuit structure 160a is sandwiched between substrate 110 and the plurality of bonding pad groups 120a. At least a portion of the driving circuit structure 160a is electrically connected to the plurality of bonding pad groups 120a. The plurality of pixel structures PX2 are arranged in the first direction d1 with first spacing P₁. The plurality of pixel structures PX2 are arranged in the second direction d2 with second spacing P₂, wherein first direction d1 and second direction d2 are interlaced. Each of the pixel structure PX2 is disposed within the pixel region R2. The first pseudo straight line L1 is parallel to the second direction d2. The first pseudo straight line L1 is separated from the bonding pad group geometric center C of the pixel structure PX2 by a distance A1 in the first direction d1, the distance A1 is

$$\frac{{P}_{1}}{2} .$$

The second pseudo straight line L2 is parallel to the second direction d2. The second pseudo straight line L2 is separated from the bonding pad group geometric center C of the pixel structure PX2 by a distance A2 in the third direction d3 opposite to the first direction d1, the distance A2 is

$$\frac{{P}_{1}}{2} .$$

The third pseudo straight line L3 is parallel to the first direction d1. The third pseudo straight line L3 is separated from the bonding pad group geometric center C of the pixel structure PX2 by a distance A3 in the second direction d2, the distance A3 is

$$\frac{{P}_{2}}{2} .$$

The fourth pseudo straight line L4 is parallel to the first direction d1. The fourth pseudo straight line L4 is separated from the bonding pad group geometric center C of the pixel structure PX2 by a distance A4 in the fourth direction d4 opposite to the second direction d2, the distance A4 is

$$\frac{{P}_{2}}{2} .$$

The pixel region R2 is enclosed by the first pseudo straight line L1, the second distance A4 is pseudo straight line L2, the third pseudo straight line L3, and the fourth pseudo straight line L4. The effective area of the pixel region R2 is the difference between the total area of the pixel region R2 and the area of the plurality of bonding pad groups 120a within the pixel region R2. Within the pixel region R2, the driving circuit structure 160a has a low absorption region R2a located outside the plurality of bonding pad groups 120a. The absorption rate of low absorption region R2a to a laser is less than the absorption rate of the plurality of bonding pad groups 120a to the laser. The area of the low absorption region R2a is greater than 60% of the effective area and less than 90% of the effective area.

Different from the aforementioned display apparatus 10: in this embodiment, low absorption region R2a may include not only a light transmissive region 110t but also a no light transmissive material region 110s. The driving circuit structure 160a of the display apparatus 10a in this embodiment has a no light transmissive material region 110s located outside the plurality of bonding pad groups 120a. The no light transmissive material region 110s of the driving circuit structure 160a is a low absorption metal layer. The low absorption metal layer is located within the low absorption region R2a of the pixel region R2. Under the laser L having the same wavelength, the absorption rate of the low absorption region R2a to the laser L is less than the absorption rate of the bonding pads 122 of the plurality of bonding pad groups 120a to the laser L. The area of the low absorption region R2a is greater than 60% of the effective area and less than 90% of the effective area. The driving circuit structure 160a may surround bonding pad group 120a. The driving circuit structure 160a includes a plurality of metal layers 162, 164, 166. A portion of the metal layer 164 extends beyond the metal layer 162 and extends toward the bonding pad 122. A portion of the metal layer 166 extends beyond the bonding pad 122.

Since the components within the no light transmissive material region 110s of the low absorption region R2a (for example, the low absorption metal layer of the driving circuit structure 160) and the light transmissive region 110t have lower absorption rates to the laser L, if the sum of areas of the no light transmissive material region 110s and the light transmissive region 110t of low absorption region R2a occupies too high a proportion within the pixel region R2 (for example, higher than 90% of the effective area), the solder 152 may not be effectively heated and thus difficult to melt. If the proportion of the low absorption region R2a within the pixel region R2 is too low (for example, lower than 60% of the effective area), structures within the pixel region R2 may easily be damaged due to absorbing excessive laser L energy and generate bubbles.

In some embodiments, by maintaining the proportion of the low absorption region R2a within the pixel region R2 in a specific range (i.e., greater than 60% of the effective area and less than 90% of the effective area), during the laser bonding process, the solder 152 may be smoothly melted while maintaining a relatively low temperature within the low absorption region R2a so that the structures within the pixel region R2 are not damaged or generate bubbles. In detail, the display apparatus 10a may effectively reduce problems such as displacement and bubble formation of the light emitting elements 130 during the bonding process with bonding pads 122 by maintaining the sum of areas of the low absorption region R2a within a specific range, thereby improving the manufacturing yield of the display apparatus 10a. For example, in a 31-inch display apparatus 10a, the area of the low absorption region R2a may be less than or equal to 87% of the effective area.

In some embodiments, the metal layer 164 may be high absorption metal, and is located within high absorption region R2b. The area of the light transmissive region 110t of the display apparatus 10a is very small, the display apparatus 10a may be a non-transparent display, but the present disclosure is not limited thereto. In some embodiments, the material of the bonding pad 122 includes titanium, the material of components within the no light transmissive material region 110s of the low absorption region R2a includes low absorption metal that has an absorption rate to the laser L lower than the absorption rate of titanium to the L under the laser L having the same wavelength, such as but not limited to: aluminum, copper, gold, silver, or alloys of at least two of aluminum, copper, gold and silver. In some embodiments, the material of the bonding pad 122 includes aluminum, the material of components of the no light transmissive material region 110s of the low absorption region R2a includes a low absorption metal that has an absorption rate to the laser L lower than the absorption rate of the bonding pad 122 to the laser L under the laser L having the same wavelength. In some embodiments, the high absorption rate to the laser L means that under laser illumination having the same intensity and the same wavelength, the temperature of the illuminated object is high; the low absorption rate to the laser L means that under laser illumination having the same intensity and the same wavelength, the temperature of the illuminated object is low.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display apparatus, comprising:
a substrate; and
a plurality of pixel structures disposed on the substrate, wherein each of the pixel structures comprises:
a plurality of bonding pad groups having a bonding pad group geometric center, wherein each of the bonding pad groups comprises at least one bonding pad;
a plurality of light emitting elements respectively bonded to the bonding pad groups; and
a driving circuit structure sandwiched between the substrate and the bonding pad groups, wherein at least a portion of the driving circuit structure is electrically connected to the bonding pad groups;
the pixel structures are arranged in a first direction with a first spacing, the first spacing is P₁, the pixel structures are arranged in a second direction with a second spacing, the second spacing is P₂, wherein the first direction and the second direction are interlaced;
each of the pixel structures is disposed within a pixel region, a first pseudo straight line is parallel to the second direction, the first pseudo straight line and the bonding pad group geometric center of the pixel structure are separated by
$$\frac{{P}_{1}}{2}$$
in the first direction, a second pseudo straight line is parallel to the second direction, the second pseudo straight line and the bonding pad group geometric center of the pixel structure are separated by
$$\frac{{P}_{1}}{2}$$
in a third direction opposite to the first direction, a third pseudo straight line is parallel to the first direction, the third pseudo straight line and the bonding pad group geometric center of the pixel structure are separated by
$$\frac{{P}_{2}}{2}$$
in the second direction, a fourth pseudo straight line is parallel to the first direction, the fourth pseudo straight line and the bonding pad group geometric center of the pixel structure are separated by
$$\frac{{P}_{2}}{2}$$
in a fourth direction opposite to the second direction, and the pixel region is enclosed by the first pseudo straight line, the second pseudo straight line, the third pseudo straight line and the fourth pseudo straight line;
the pixel region has an effective area that is a difference between a total area of the pixel region and areas of the bonding pad groups within the pixel region;
there is a low absorption region within the pixel region, an absorption rate of the low absorption region to a laser is less than an absorption rate of the bonding pad groups to the laser, an area of the low absorption region is greater than 60% of the effective area and less than 90% of the effective area.

2. The display apparatus as described in claim 1, wherein within the pixel region, the driving circuit structure further has a high absorption region located outside the bonding pad groups, an absorption rate of the high absorption region to the laser is greater than or equal to the absorption rate of the bonding pad groups to the laser, an area of the high absorption region within the pixel region is greater than 10% of the effective area and less than 40% of the effective area.

3. The display apparatus as described in claim 1, wherein the first direction and the second direction are perpendicular to each other.

4. The display apparatus as described in claim 1, wherein a material of the at least one bonding pad comprises titanium, a material of the low absorption region of the driving circuit structure comprises aluminum, copper, gold, silver, or an alloy of at least two of aluminum, copper, gold and silver.

5. The display apparatus as described in claim 1, wherein the area of the low absorption region is less than or equal to 87% of the effective area.

6. The display apparatus as described in claim 1, wherein the low absorption region comprises a no light transmissive material region and a light transmissive region.

7. A display apparatus, comprising:
a substrate; and
a plurality of pixel structures disposed on the substrate, wherein each of the pixel structures comprises:
a plurality of bonding pad groups having a bonding pad group geometric center, wherein each of the bonding pad groups comprises at least one bonding pad;
a plurality of light emitting elements respectively bonded to the bonding pad groups; and
a driving circuit structure sandwiched between the substrate and the bonding pad groups, wherein at least a portion of the driving circuit structure is electrically connected to the bonding pad groups;
a plurality of pixel structures are a plurality of repeating units, each of the pixel structures is disposed within a pixel region;
an effective area of the pixel region is a difference between a total area of the pixel region and areas of the bonding pad groups within the pixel region;
there is a low absorption region within the pixel region, an absorption rate of the low absorption region to a laser is less than an absorption rate of the bonding pad groups to the laser, an area of the low absorption region is greater than 60% of the effective area and less than 90% of the effective area.

8. The display apparatus as described in claim 7, wherein within the pixel region, the driving circuit structure further comprises a high absorption region located outside the bonding pad groups, an absorption rate of the high absorption region to the laser that is greater than or equal to the absorption rate of the bonding pad groups to the laser, the area of the high absorption region within the pixel region is greater than 10% of the effective area and less than 40% of the effective area.

9. The display apparatus as described in claim 7, wherein the area of the low absorption region is less than or equal to 87% of the effective area.

10. The display apparatus as described in claim 7, wherein the low absorption region comprises a no light transmissive material region and a light transmissive region.
